(19) United States
(12) Patent Application Publication
(10) Pub. No.: US 2011/0209746 A1
(43) Pub. Date: Sep. 1, 2011

(54) Tubular Photovoltaic Device and Method of Making

(76) Inventors: Hanzhong Zhang, Santa Clara, CA (US); Jian Li, Fremont, CA (US)

(21) Appl. No.: 12/875,725

(22) Filed: Sep. 3, 2010

Related U.S. Application Data
(60) Provisional application No. 61/240,227, filed on Sep. 6, 2009.
(60) Provisional application No. 61/245,657, filed on Sep. 24, 2009.

(51) Int. Cl. H01L 31/048; H01L 31/0203; H01L 31/18

(52) U.S. Cl. 136/251; 136/259; 118/723 E; 438/57; 257/E31.001

(57) ABSTRACT

A tubular photovoltaic device capable of collecting light from a variety of angles is disclosed. The tubular photovoltaic device is sealed at an end with a sealing ring and hermetic sealing cap. Novel deposition electrodes and processes for depositing thin films inside a tubular substrate are also disclosed.

### CROSS REFERENCE TO RELATED APPLICATIONS

This application claims priority to U.S. Provisional Application No. 61/240,227, filed Sep. 6, 2009 and to U.S. Provisional Application No. 61/245,657, filed Sep. 24, 2009 the contents of both are incorporated herein by reference.

### BACKGROUND OF THE INVENTION

Innovative solar technologies are seen by many as the best way to solve the world's energy problems. Increasing solar conversion efficiency is the goal of many who strive to improve solar technologies. It is well known that the incident angle of sunlight varies and this can affect the photovoltaic device performance. Prior art flat panel solar modules collect sunlight effectively from a limited range of incident angles thus collecting only a percentage of available light. However tubular solar modules in accordance with this invention collect sunlight from a great array of angles. This provides for increased efficiency. M.D. Archbold and Halliday, Photovoltaic Specialists Conference 2008, Novel tubular geometry CdTe/CdS devices, PVSC '08. 33rd IEEE, Issue Date: 11-16 May 2008, the contents of which are incorporated herein by reference discloses tubular photovoltaic devices having a thin film stack on the inside of the substrate, see FIG. 1A.

Another shortcoming of the prior art is that some prior art tubular cells require a second tube for encapsulation. Encapsulation is necessary to protect the thin films from environmental degradation. Buller et al. U.S. Pat. No. 7,235,736 B1, the contents of which are incorporated herein by reference discloses a tubular solar cell having a thin film stack on the outside surface of a tubular substrate which is encapsulated by a second tube. Because of the structure of the devices disclosed herein the need for a second encapsulation tube is eliminated.

Prior art deposition techniques for forming thin films on flat panels or the inside of tubular substrates continue to strive to improve thin film quality and uniformity. Various electrode configurations and structures have been shown, but none satisfactorily create a device grade thin film on the inside surface of a tubular substrate. Keshner et al. US Pub. No. 2007/0048456 A1, the contents of which are incorporated herein by reference discloses a substrate processing system including a deposition chamber and a plurality of tubular electrodes positioned linearly within the deposition chamber defining plasma regions adjacent thereto. Matsuda et al. U.S. Pat. No. 6,189,485 B1, the contents of which are incorporated herein by reference discloses a plasma based on electric discharge excitation in the front space of a flat substrate, and depositing an amorphous silicon thin film on the substrate by plasma enhanced chemical vapor deposition. An electrode section comprising tubular electrodes supplies the material gas through a plurality of gas discharge openings, and tubular electrodes evacuate gases to the outside through a plurality of gas suction openings. DE102004020185 (A1), the contents of which are incorporated herein by reference discloses depositing barrier layers on the inside of bottles.

Prior art electrodes for tubular deposition are disclosed in Miljevic, V. “Optical characteristics of the hollow anode discharge”, J. Appl. Phys. 59 (2), 15 Jan. 1986, the contents of which are incorporated herein by reference disclose a concave cathode. Anders et al. in U.S. Pat. No. 6,137,231, the contents of which are incorporated herein by reference discloses a constricted glow discharge chamber for plasma deposition.

### SUMMARY OF THE INVENTION

Disclosed herein is a photovoltaic device comprising a tubular substrate, a transparent conductive layer disposed inside said substrate, a semiconductor junction layer disposed on said transparent conductive layer, and a back electrode disposed on said semiconductor junction layer. In one embodiment of the invention there is at least one sealing ring disposed at an end of the photovoltaic device. In one embodiment a sealing cap is attached to the sealing ring and the device is hermetically sealed. In one embodiment of the invention the device comprises a plurality of photovoltaic cells separated grooves. In one embodiment of the invention each of said plurality of photovoltaic cells is the same or different. In one embodiment of the invention the groove extends non-orthogonally around the tube. In one embodiment of the invention the back electrode is transparent. In one embodiment of the invention there a second device disposed inside the photovoltaic device, said second device is selected from the group consisting of a photovoltaic device or a battery. The internal photovoltaic device may comprise a similar or different device capable of collecting light at the same or different wavelengths. In one embodiment of the invention there is a reflective surface on a portion of a surface of an outer surface of the tubular device. The reflective surface may cover all or a portion of the device. The reflective surface may comprise any suitable coating or other film applied by a variety of methods.

In one embodiment of the invention a method for forming a thin film is disclosed comprising generating a plasma inside a tube using one or more electrodes wherein the plasma is configured to coat the inside of the tube uniformly. In one embodiment of the invention the plasma is generated using an even number of electrodes distributed at an equidistance symmetrically arranged around a center axis of the tube. In one embodiment of the invention the plasma is generated between adjacent electrodes. In one embodiment of the invention the tube does rotate during deposition. In one embodiment of the invention the plasma is generated using odd number of electrodes distributed at an equidistance symmetrically arranged around a center axis of the tube. In one embodiment of the invention the plasma is generated in the center of the tube. In one embodiment of the invention the plasma is rotating circumferentially inside the tube. In one embodiment of the invention the process gas is delivered by a hollow electrode or a hollow insulator. In another embodiment the electrode comprises a shield to keep the plasma out of the hollow tubular central portion.

In another embodiment of the invention there is disclosed an electrode comprising a hollow tubular central portion, at least two gas discharge chambers in communication with said hollow tubular central portion through a gas inlet opening, said gas discharge chamber has a gas discharge chamber opening designed to communicate with an anode, and said gas discharge chamber has a concave surface whereby when a gas is fed through said gas inlet opening and through said gas discharge chamber opening, a plasma is created. In another embodiment the electrode comprises four gas discharge chambers.

### BRIEF DESCRIPTION OF THE DRAWINGS

FIGS. 1A and 1B are cross sectional views of prior art tubular photovoltaic devices.

FIGS. 2A and 2B are a side view and corresponding cross sectional view respectively of a tubular photovoltaic device in accordance with one embodiment of the invention having a sealing ring and hermetic seal cap, ring and cap not shown in FIG. 2B.

FIGS. 3A and 3B are a side view and a corresponding cross sectional view illustrating grooves orthogonal to the tube's axis dividing a tubular photovoltaic device into cells.

FIG. 4 is a side view illustrating non-orthogonal grooves dividing a tubular photovoltaic device into cells.

FIG. 5 is a corresponding cross sectional view to FIG. 4.

FIGS. 6A and 6B are a side view and a cross sectional view of a device comprising curved grooves dividing the device into cells which enhance the aspect ratio of the cells.

FIG. 7 shows a curve of the aspect ratio gain versus the groove Sinusoidal Frequency.

FIGS. 8A and 8B show a side view and cross sectional view respectively illustrating a photovoltaic device having an encapsulation layer.

FIG. 9 is a side view of a tubular photovoltaic device having a sealing ring and cap at an end.

FIG. 10 illustrates a manufacturing scheme for a tubular photovoltaic device.

FIGS. 11A and 11B show a side view and a cross sectional view of a tubular photovoltaic device partially manufactured after scribing the semiconductor junction layer.

FIG. 12 shows a cross sectional view of a tubular photovoltaic device having a substrate layer, a transparent conductive layer, a semiconductor junction layer and a back electrode layer and grooves through the back electrode layer and the semiconductor junction layer.

FIG. 13 illustrates a photovoltaic tubular device with a sealing ring and sealing cap for hermetic sealing.

FIG. 14 illustrates a common platform for thin film deposition where multiple tubes can be processed at one time.

FIG. 15 illustrates a process and apparatus in which a multi-zone vapor distribution system is utilized to facilitate the even gas distribution axially inside a tubular substrate with independent gas flow for each zone.

FIG. 16 illustrates a process and apparatus in which an even number of electrodes are arranged inside a tubular substrate for thin film deposition on the substrate inner surface.

FIG. 17 illustrates a process and an apparatus in which an odd number of electrodes are arranged inside a tubular substrate for thin film deposition on the substrate inner surface.

FIG. 18 illustrates a process and apparatus for thin film deposition on the inside of a tubular substrate comprising a novel electrode arrangement to create a plasma inside the tube.

FIG. 19 illustrates a process and apparatus for thin film deposition on the inside of a tubular substrate comprising a novel hollow cathode having a concave outer surface.

FIG. 20 illustrates a process and an apparatus where a thin film is deposited on the inside of a tubular substrate using a preinstalled seal on the tubular substrate to contain gas effluent during processing.

FIG. 21 illustrates a process and apparatus in which a magnetron is used for physical vapor deposition process inside a tubular substrate.

FIG. 22 illustrates a perspective view of a stand-alone vertically stacked load lock chamber and process chamber for depositing thin films on tubular substrates.

FIG. 23 illustrates the arrangement of multiple stand-alone process system around an industry robot.

FIG. 24 illustrates a perspective, cutaway view of a clustered configuration comprising a common buffer chamber to deposit thin films inside tubular substrates.

FIG. 25 illustrates a perspective view of a horizontally arranged clustered common platform

FIG. 26 illustrates a diagram of a film deposition apparatus for depositing thin films inside tubular substrates.

FIG. 27 illustrates a perspective view of a tubular substrate handling system which transfers tubular substrates between a process chamber and a load lock chamber in stand-alone configuration or between the process chamber and the common buffer chamber in the clustered configuration.

FIG. 28 illustrates a perspective view of a tubular substrate handling system which transfers tubular substrates between a process chamber and a load lock chamber in stand-alone configuration or between a process chamber and a common buffer chamber in a clustered configuration.

FIG. 29 illustrates a tubular substrate holding and rotating mechanism in a process chamber.

### DETAILED DESCRIPTION OF THE EMBODIMENTS

Reference will now be made in detail to some specific embodiments of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In this specification and the appended claims, the singular forms “a,” “an,” and “the” include plural reference unless the context clearly dictates otherwise. Unless defined otherwise, all technical and scientific terms used herein have the same meaning as commonly understood to one of ordinary skill in the art to which this invention belongs.

By “photovoltaic device” it is meant a device comprising a single cell or multiple cells capable of converting photons to electricity. The use of the term does not mean that every element of the device be present to afford the capability of converting photons to electricity, but that as used and claimed a “photovoltaic device” has the ability, with appropriate connection and bus wiring of converting photons to electricity. Photovoltaic devices according to the present invention are not limited to tubular substrates but include all non-flat substrates.

As used herein “layer” means a single film or thin film, or a combination of one or more films and/or thin films. Herein “layer” and “thin film” may be used interchangeable where it does not depart from the scope of the invention.

By “forming a film” it is meant any deposition or process that results in a thin film.

By “cell” it is meant a portion of a photovoltaic device that converts solar energy into electrical energy. The cells of a photovoltaic device of this invention may be independently the same or different as to size, compositional makeup as to materials and thin films, grooves and aspect ratio.

By “hermetic seal” it is meant a seal or a condition which is considered approximately, reasonably or completely airtight.

By “circumferentially” it is meant “around the circumference”. The invention is not limited to meaning the entire circumference, but that is a preferred embodiment.

By “tubular” it is meant hollow and open at one or more ends. The invention is not limited to cylindrical tubes or round tubes, but contemplates that any shape is within the scope of the present definition. Tubes whose walls comprise abstract shapes are within the scope of the current invention. Preferably the tube is circumferentially integral, i.e. an unbroken substrate. However photovoltaic devices according to the instant invention may comprise tubes that actually semi-circles or half circles and/or concave shapes.

By “concave” it is meant curved like the inner surface of a sphere. The degree or amount of curvature may change along the surface of the discharge cavity.

Another advantage of the process for making a tubular device disclosed herein is that the thin film may be deposited after the sealing ring is placed on the tube, said sealing ring installation typically requires a temperature above 400° C. Thin films are typically deposited at the temperature preferably lower than 300° C., more preferably lower than 250° C., even more preferably between 100° C. to 200° C. The present method seals tubes with a hermetic seal cap at a lower temperature, preferably lower than 250° C., even more preferably 200° C., even more preferably between about 20° C. and 100° C.

It is known that longer photon path increases light absorption thus increases PV conversion efficiency. Due to the well-known Light-Induced-Degradation, however, hydrogenated amorphous silicon (a-Si:H) film has a limit on its thickness to further increase photon path. This is one of the reasons why a-Si:H suffers low efficiency. The tubular geometry disclosed herein remedies this prior art problem by prolonging photon path without adding film thickness. Additionally, diffused light, which accounts for about 25% of daylight, can also be better absorbed due to the three times increased surface area with tubular shape. The inherent bi-facial feature of tubes of the present invention, the light trapping between tubes and the proposed transparent film stacks further improves the conversion efficiency.

Prior art encapsulation of flat solar panels is largely accomplished by lamination methods together with an edge delete process to delay the penetration of oxygen and water vapor, which is detrimental to film quality. Prior art tubular devices require a second glass tube concentric with the solar cell tube and in order to collect the light between the two tubes, a liquid such as silicone oil is used to refract light to the inner tube. The current invention does not require the lamination and edge delete processes required to make flat solar panels. The current invention also eliminates the necessity of a second glass tube and the liquid required by some prior art tubular devices. This significantly reduces the material cost of substrates, which is a major contributor to total device cost.

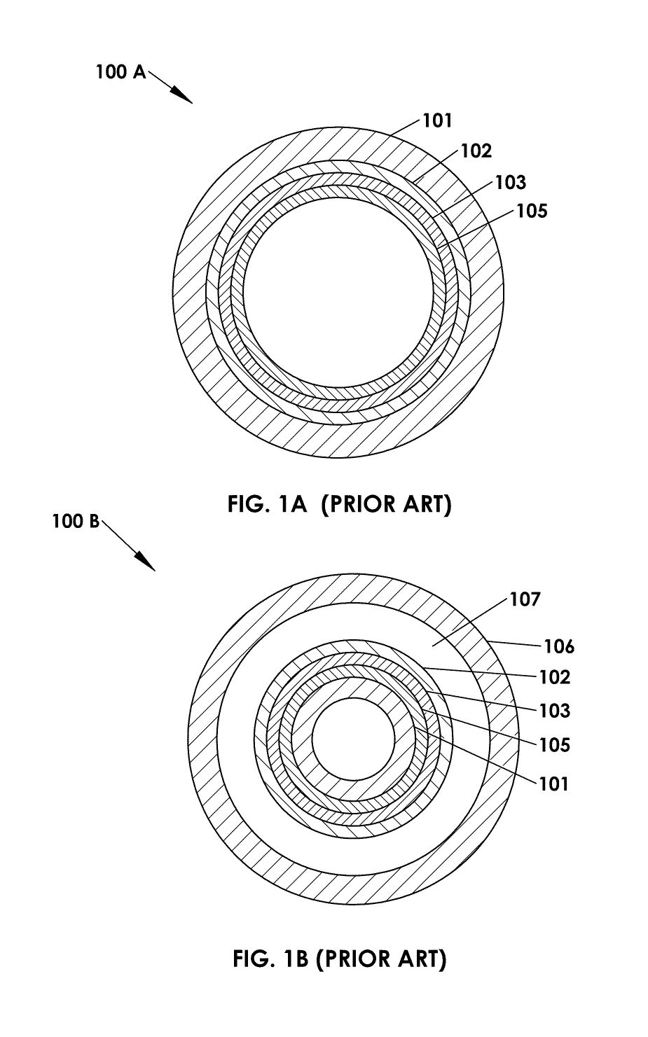

FIG. 1A illustrates the structure of a prior art tubular photovoltaic cell 100A. Substrate 101 has an inner thin film covered with transparent conductive thin film 102, followed by a semiconductor junction thin film 103. A back electrode thin film 105 covers the semiconductor junction thin film 103. One skilled in the art readily recognizes that an absorber thin film and window thin film (not illustrated in this figure) in combination form a p-n junction or n-p and is termed herein a semiconductor junction thin film.

FIG. 1B illustrates another prior art tubular photovoltaic device 100B. Substrate 101 has an outer thin film covered with a back electrode thin film 105, followed by a semiconductor junction thin film 103. A transparent conductive thin film 102 covers the semiconductor junction thin film 103. In order to protect the film stacks from exposure to ambient environment, a tubular casing 106 is used. In operation an optical coupling media is use to fill up the gap 107 between the transparent tubular casing 106 and transparent conductive thin film 102.

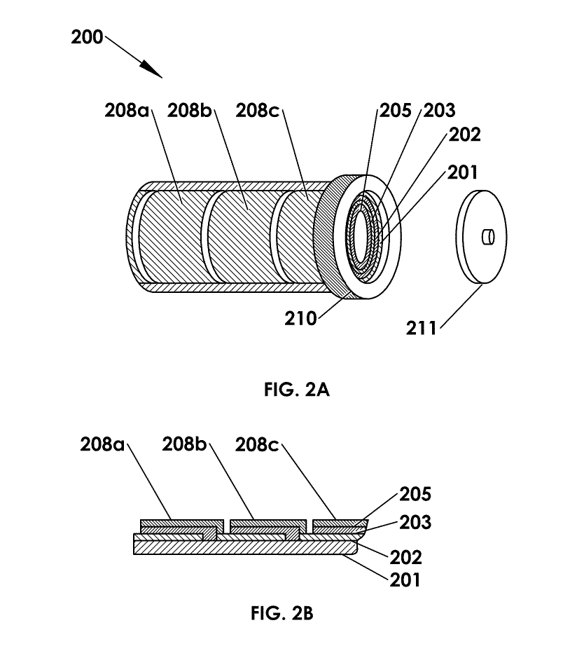

FIG. 2 shows a cross sectional view of a tubular photovoltaic device in accordance with one embodiment of the invention. Tubular photovoltaic device 200 has on its inner surface or inwardly facing surface a transparent conductive thin film 202, followed by a semiconductor junction layer 203 which is covered with a back electrode thin film 205. Semiconductor junction layer 203 comprises an absorber thin film (not illustrated) and a window thin film (not illustrated) in combination to form a junction. The substrate 201 is transparent or substantially transparent and may comprise aluminosilicate glass, borosilicate glass, dichroic glass, germanium/semiconductor glass, glass ceramic, silicate/fused silica glass, soda lime glass, quartz glass, chalcogenide/sulphide glass, fluoride glass, a glass based phenolic, flint glass and transparent plastics. The transparent conductive thin film 202 may comprise carbon-nanotubes, graphene, tin oxide, SnOₓ (with or without fluorine doping), indium-tin oxide (ITO), doped zinc oxide (e.g., aluminum doped zinc oxide, indium-zinc oxide, gallium doped zinc oxide, boron doped zinc oxide, or any combination thereof). Transparent conductive thin film 202 may be either p-doped or n-doped. For example, in embodiments where the semiconductor junction layer 203 is p-doped, transparent conductive thin film 202 can be p-doped. Transparent conductive thin film 202 is preferably made of a material that has very low resistance, suitable optical transmission property (preferably greater than 90%). Preferably the transparent conductive thin film 202 is textured to maximize the light absorption.

Semiconductor junction layer 203 may comprise any photovoltaic homojunction, heterojunction, heteroface junction, buried homojunction, a p-i-n junction, a tandem junction or a triple junction having an absorber layer that is direct band gap absorber (e.g., CdTe) or an indirect band-gap absorber (e.g., crystalline silicon). For example, the semiconductor material may comprise an amorphous-Si single junction, amorphous-Si/microcrystalline tandem junction, and/or a CdTe/CdS heterojunction.

The back-electrode 205 may comprise any material capable of supporting photovoltaic current with negligible resistive losses. The back-electrode 205 may comprise a conductive material such as aluminum, molybdenum, tungsten, vanadium, rhodium, niobium, chromium, tantalum, titanium, steel, nickel, platinum, silver, gold, an alloy thereof, or any combination thereof. In some embodiments, the back-electrode 205 comprises partly or fully transparent conductive oxide, such as indium tin oxide, aluminum doped zinc oxide, gallium doped zinc oxide or boron doped zinc oxide or indium-zinc oxide.

In addition to materials disclosed herein materials suitable for the layers disclosed herein and other methods for making such a device than disclosed herein are disclosed in U.S. Pat. No. 7,235,736 the contents of which are incorporated herein by reference.

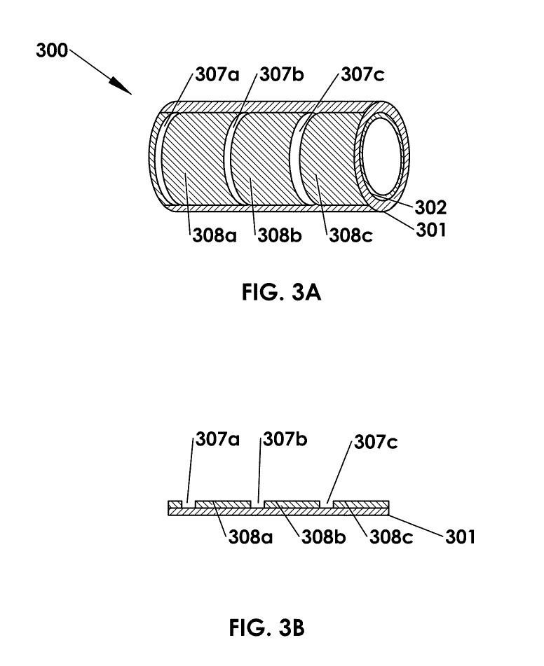

FIG. 3A shows a side view of a tubular solar device in accordance with one embodiment of the invention. Tubular photovoltaic device 300 comprises substrate 301 that has deposited on an inner surface a transparent conductive layer 302. Substrate 301 is partially removed for clarity in the picture to illustrate the detail underneath. Specifically grooves 307a, 307b and 307c are scribed through the transparent conductive layer 302 to define cells 308a, 308b and 308c. FIG. 3B shows a cross sectional view of a portion of the photovoltaic device illustrated in FIG. 3A. FIG. 3B depicts a flat substrate; this is for clarity only and does not limit the invention. FIG. 3B illustrates substrate 301 having cells, 308a, 308b and 308c separated by grooves 307a, 307b and 307c.

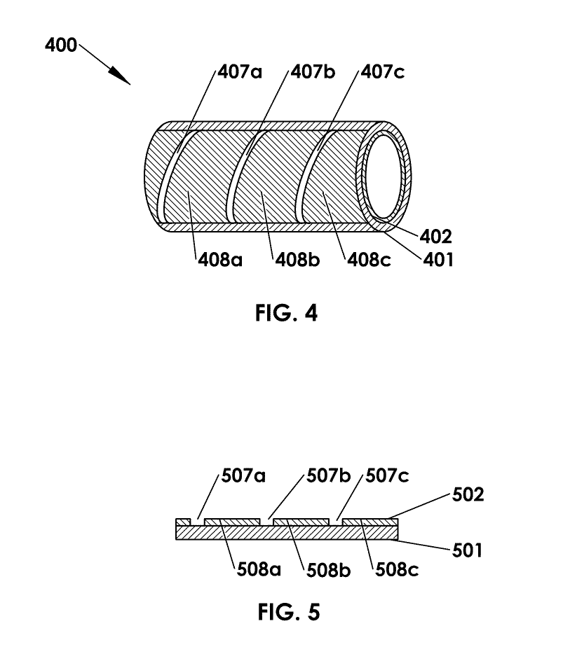

FIG. 4 shows a side view of a tubular solar device in accordance with one embodiment of the invention. Tubular photovoltaic device 400 comprises substrate 401 that has deposited on an inner surface a transparent conductive layer 402. Substrate 401 is partially removed for clarity in the picture to illustrate the detail underneath. Grooves 407a, 407b and 407c are scribed through the transparent conductive layer 402 to define cells 408a, 408b and 408c. Grooves 407a, 407b and 407c are independently the same or different and can extend partially or wholly around the tube and in one embodiment extend non orthogonally to an axis down the center of the tube. The angle of the grove to the central axis may be between 0 and 60 degrees, preferably between 5 and 50 degrees and more preferably between 30 and 45 degrees. It is preferred that the angle be 45 degrees. FIG. 5 shows a cross sectional view of a portion of the photovoltaic device illustrated in FIG. 4. FIG. 5 depicts a flat view, this is for clarity only and does not limit the invention. FIG. 5 illustrates substrate 501 having deposited there on cells 508a, 508b and 508c separated by grooves 507a, 507b and 507c. Grooves 507a, 507b and 507c independently or together may extend orthogonally to an axis down a center of the tube or extend in an predetermined angle to the axis.

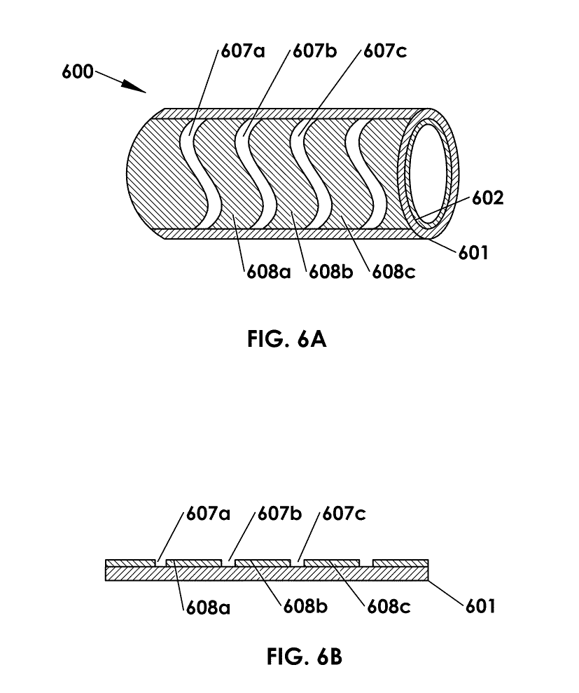

FIGS. 6A and 6B show a side view and corresponding cross sectional view of a tubular photovoltaic device where cells have a different aspect ratio. Tubular photovoltaic device 600 comprises substrate 601 that has deposited on an inner surface a transparent conductive layer 602. Substrate 601 is partially removed for clarity in the picture to illustrate the detail underneath. Grooves 607a, 607b and 607c are scribed through the transparent conductive layer 602 to define cells 608a, 608b and 608c. Grooves 607a, 607b and 607c are independently the same or different and can extend partially or wholly around the tube and have sinusoidal or approximate sinusoidal shapes. FIG. 6B shows a cross sectional view of a portion of the photovoltaic device illustrated in FIG. 6A. FIG. 6B depicts a flat substrate 601 this is for clarity only and does not limit the invention. FIG. 6B illustrates substrate 601 having deposited there on cells 608a, 608b and 608c separated by grooves 607a, 607b and 607c.

In order to reduce the ohmic sheet resistance of the transparent conductive layer, it is desired to have a large aspect ratio solar cell 608a, i.e., the ratio of circumference of the cell 608a to the width of the cell 608a. Increasing the aspect ratio of the cell lowers the overall series resistance of the cell resulting in increased fill factor and the device conversion efficiency. By using a specific cut for the groove the aspect ratio of the front and back conduction layer of the cell will be increased. This results in lower ohmic loses or loses due to resistance, and a concomitant increase in efficiency. For example a regular cut aspect ratio=2πR/30, assuming a 60 mm diameter tube with a 30 mm cell width. Thus a regular cut aspect ratio=6.3. For a tilting cut of 45 degrees:aspect ratio=2.8πR/30=8.8, which is a 40% increased in aspect ratio. For a sinusoidal cut, the increase in aspect ratio will depend on the amplitude of the deviation and period. Grooves 607a, 607b and 607c are independently the same or different and may comprise a geometric shape where the width varies along the length of the groove.

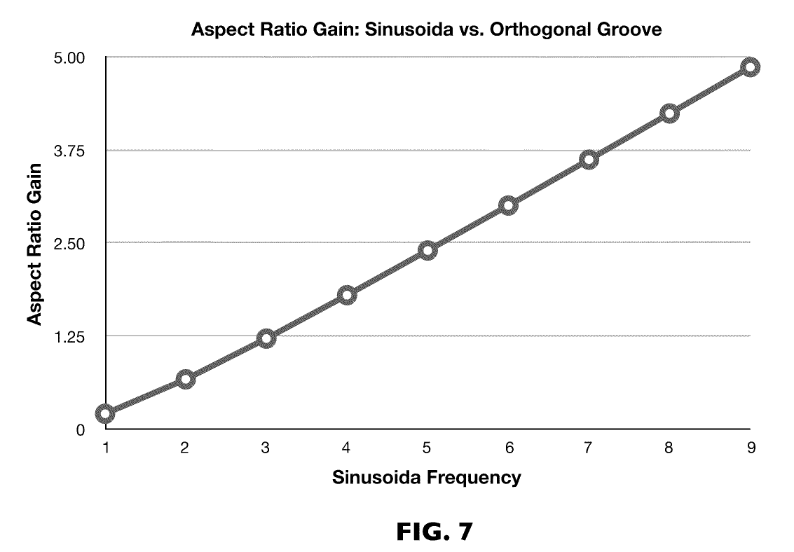

FIG. 7 shows the aspect ratio gain of sinusoidal curved grooves over orthogonal grooves plotted against the alternating frequency of the sinusoidal curved grooves. It can be seen that the cell aspect ratio increases 2.5 times if the alternating frequency increases 5 times.

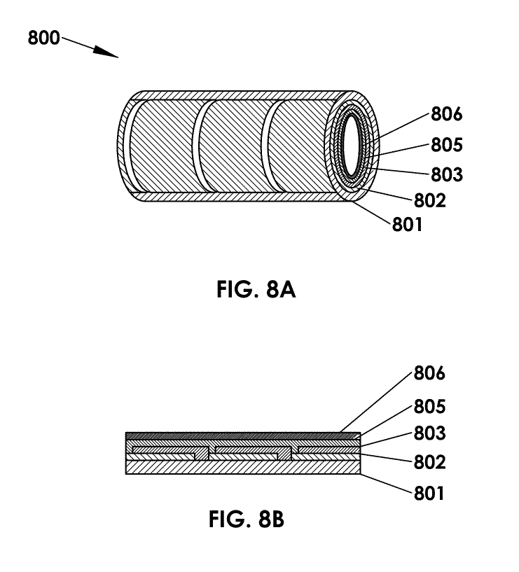

FIG. 8A shows a side view of a tubular solar device in accordance with one embodiment of the invention. Tubular photovoltaic device 800 comprises substrate 801 that has deposited on an inner surface a transparent conductive layer 802. Substrate 801 is partially removed for clarity in the picture to illustrate the detail underneath. Deposited on top of the transparent conductive layer is a semiconductor junction layer 803. Deposited on top of the semiconductor junction layer 803 is a back contact layer 805. Encapsulating layer 806 covers the back contact layer 805. With an encapsulation layer an optional hermetic seal may not be necessary. FIG. 8B shows a cross sectional view of a portion of the photovoltaic device illustrated in FIG. 8A. FIG. 8B depicts a flat substrate, this is for clarity only and does not limit the invention. Substrate 801 has deposited on an inner surface a transparent conductive layer 802. Substrate 801 is partially removed for clarity in the picture to illustrate the detail underneath. Deposited on top of the transparent conductive layer is a semiconductor junction layer 803. Deposited on top of the semiconductor junction layer 803 is a back contact layer 805. Encapsulating layer 806 covers the back contact layer 805.

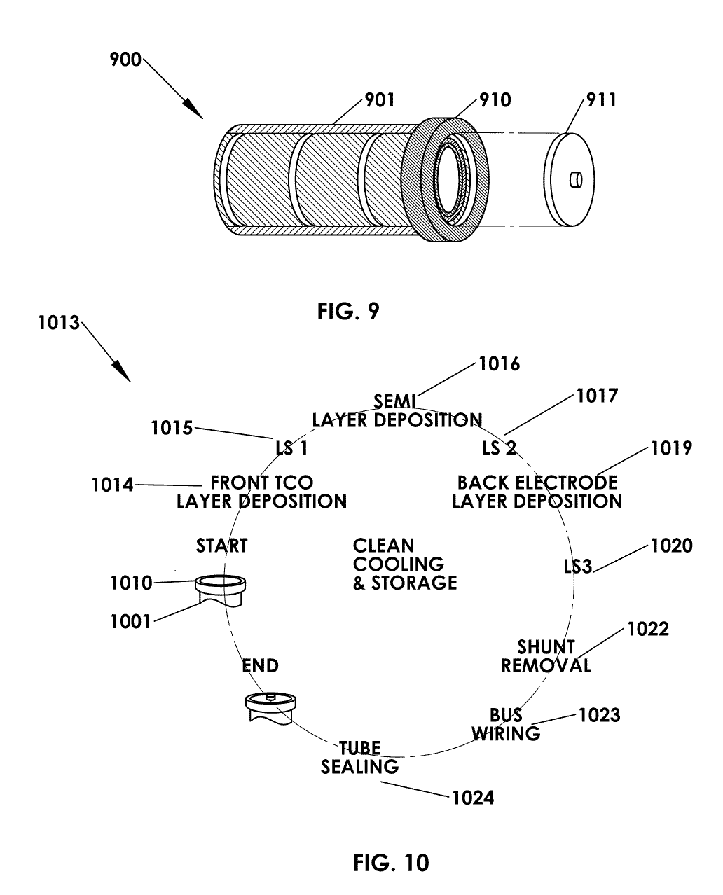

FIG. 9 shows a side view of a tubular photovoltaic device 900 having a sealing ring 910 at an end. Preferably the solar device 900 is hermetically sealed to prevent oxygen or water vapor from damaging the film stacks. In one preferred embodiment of the invention, the tubular substrate 901 is sealed by welding or otherwise affixing a sealing cap 911 onto sealing ring 910 which is hermetically sealed with the tubular substrate. Sealing rings may comprise any material suitable, preferably a metal or metal alloy is used. Cap 911 may be attached to the sealing ring under a vacuum environment so that photovoltaic device 900 has a vacuum inside. Alternatively the interior of the device may be filled with a gas such as argon or other inert and/or nitrogen, or any other suitable gas or combination, to create positive pressure to prevent harmful elements from contacting the film stacks. Any suitable material can be used for the hermetical sealing though it is preferable that the temperature of the tubular substrate during this process is kept below 200° C. Even more preferably below 100° C., even more preferably at room temperature.

FIG. 10 shows a manufacturing scheme 1013 for a tubular photovoltaic device. In this method manufacturing tools are arranged according to their functions. Laser scribe tools, metrology tools which require special anti-vibration foundation, are located in certain locations while the more tolerant tools are installed in less expensive areas. Within each section, multiple tools may work in parallel so if a tool breaks down or is stopped for maintenance, production flow will not cease.

At either or both ends of the tubular substrate 1001, circular ring 1010 is attached. Rings may be of two colors so that the tubular substrates can be appropriately oriented during manufacturing. A bar code can be scribed onto the one of the rings for quality tracking purpose. A transparent conductive layer is circumferentially disposed on the inside of substrate 1001 using low pressure chemical vapor deposition 1014. Typical thickness of the transparent conductive layer arranges from 700 nm to 1000 nm, depending on the material used. The transparent conductive layer may be deposited by a variety of techniques. Sputtering, low pressure chemical vapor deposition method (LPCVD), atmospheric pressure chemical vapor deposition (APCVD) are non-limiting examples. Laser scribe 1015 scribes the transparent conductive layer to form grooves which separate the device into solar cells. Grooves may or may not run the full perimeter of tubular substrate; preferably they run the full length the transparent conductive layer into discrete sections. Each section serves as the front electrode of a corresponding solar cell. The bottoms of grooves expose the underlying tubular substrate. To maximize photovoltaic conversion efficiency, the grooves are narrow while the transparent conductive oxide strips are electrically isolated. For scribing, pulsed excimer and Q-switched YAG laser ablation may be used on the transparent conductive layer, examples of which are disclosed in S. Kiyama, T. Matsuoka, Y. Hirano, M. Osumi, Y. Kuwano, in “Laser patterning of integrated type a-Si solar cell submodules,” JSPE, 11, 2069 (1990), the contents of which are incorporated herein by reference. The grooves are typically approximately 25 um to 50 um wide.

The semiconductor junction layer may be deposited at stage 1016 and can be a homojunction, a heterojunction, a heteroface junction, a buried homojunction, a p-i-n junction, a tandem junction or a triple junction. In some embodiments of present invention, a single junction a-Si layer may be circumferentially deposited. Plasma enhanced chemical vapor deposition is a preferred method for the semiconductor junction layer. In another embodiment, high conversion efficient CdTe/CdS may be disposed as the semiconductor junction layer.

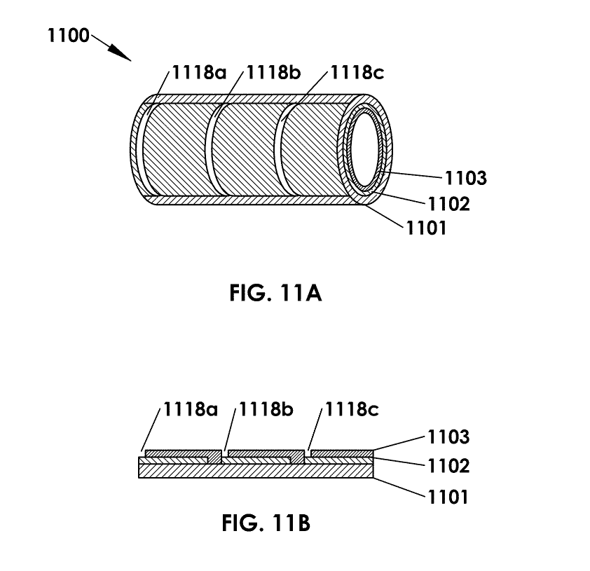

The manufacturing procedure is more completely understood with reference to FIG. 10 and FIGS. 11A and 11B. Tubular photovoltaic device 1100 comprises a semiconductor junction layer 1103 patterned by scribing grooves 1118a, 1118b and 1118c at station 1017 to separate solar cells. Grooves may run the full perimeter of tubular substrate, thereby breaking the semiconductor junction layer into discrete sections. The bottoms of grooves expose the underlying transparent conductive layer. It is preferably that the pattern of grooves 1118a, 1118b and 1118c scribed in station 1017 parallel or substantially parallel to those grooves made on the transparent conductive oxide layer. In typical applications a Nd-YAG laser of different wavelength is used to scribe the semiconductor junction layer down to the transparent conductive layers with a 25 um to 50 um offside so that grooves 1118a, 1118b and 1118c are in close proximity by the respective groove in the transparent conductive layer. Cells are connected in a monolithically integrated manner and connected serially to adjacent cells.

A back electrode layer is disposed on the scribed semiconductor junction layer in station 1019 using a suitable manufacturing method, such as a physical vapor deposition method or low pressure CVD methods. In one embodiment of the invention, aluminum doped zinc oxide layer is first circumferentially deposited onto the semiconductor junction layer either by low pressure chemical vapor deposition method or by physical vapor deposition method, then a metal layer comprising aluminum or silver for example, is disposed onto the aluminum doped zinc oxide layer. In another embodiment only a transparent conductive layer is disposed onto the semiconductor junction layer without an opaque metal layer to make solar tube semi-transparent so that the portion of tubular substrate 1001 which is not facing the sun can also generate electricity. In another embodiment a transparent conductive layer is used as back electrode to form the solar module as TCO/semiconductor junction layer/TCO. The semiconductor junction layer is captures a portion of the solar spectrum. A separate solar module is placed inside the solar module to capture the rest of the solar spectrum. In another embodiment a white paint or a reflective layer can be applied onto a surface, preferably an outer surface of a tube, so that a light may be reflected from a portion of the tube which is not facing the sun into the photovoltaic device.

The back electrode layer and the semiconductor junction layer are then patterned at station 1020. The pattern of grooves are preferably parallel or substantially parallel to those through the semiconductor junction layer with 25 um˜50 um offside. Material defects and/or shunts which may cause a short circuit through the semiconductor junction layer are removed at station 1122. Bus wiring and tube sealing may be done in stations 1023 and 1024 respectively.

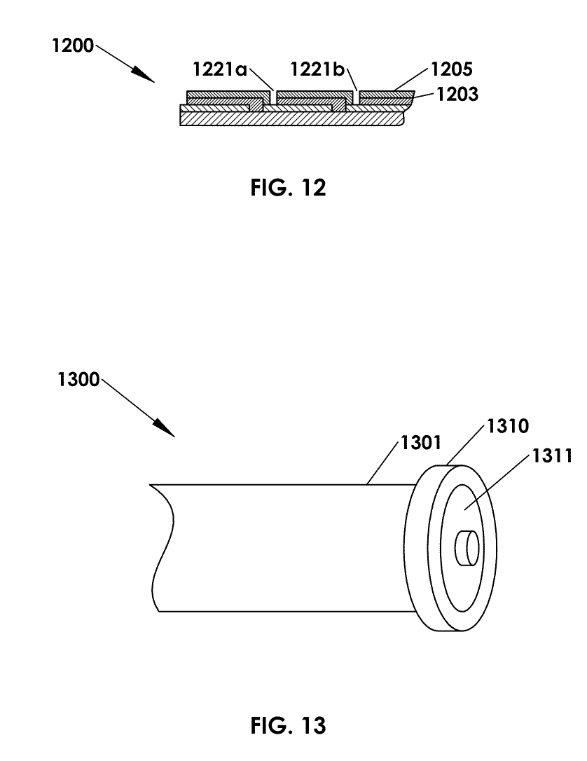

FIG. 12 shows a cross section of a photovoltaic device 1200 having back electrode layer 1205 and semiconductor junction layer 1203 and having grooves 1221a and 1221b cut through the back electrode layer 1205 and semiconductor junction layer 1203. In typical applications, a Nd-YAG laser used in the semiconductor junction layer scribing can be used to scribe the layers.

The end of the solar cells of the tubular photovoltaic device may serve as connection points where external electrical wires are connected with minimum contact ohmic resistance.

FIG. 13 illustrates a photovoltaic tubular device 1300 having a sealing ring 1310 attached to substrate 1301 and a sealing cap 1311 attached to create a hermetic seal. The photovoltaic device layers are preferably isolated from ambient vapor by hermetically sealing the device.

Optionally a passivation layer is disposed onto the back electrode layer. Optionally an electricity storage element can be inserted into the tubular substrate to create an integrated solar generation and storage device.

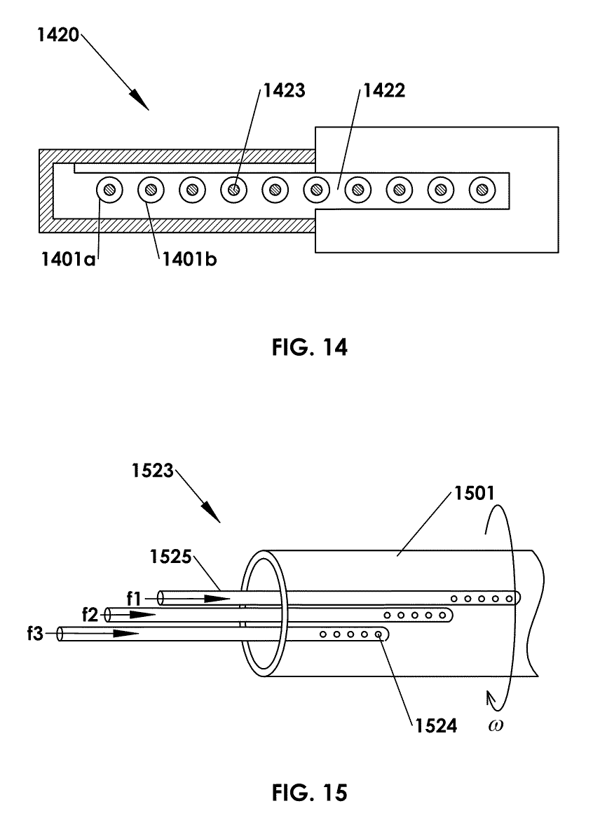

FIG. 14 illustrates a process chamber 1420 that can be used to circumferentially deposit thin film layers on the inside of a tubular substrate. Illustrated is half of the chamber 1420 in cross sectional view. Tubular substrates 1401a and 1401b are loaded into the process chamber 1420 through the slot 1422. The process unit 1423 may comprise a APCVD process unit, a LPCVD process unit or a plasma enhanced chemical vapor deposition (PECVD) process unit. A magnetron unit may be used. During deposition the tubular substrates 1401a and/or 1401b and/or the process unit 1423 may optionally rotate for uniform thin film deposition.

FIG. 15 illustrates a process for completing quality thin film deposition on the inside of a tubular substrate 1501. One or more layers of the photovoltaic device may be deposited by atmospheric pressure chemical vapor deposition (APCVD). The deposition of a SnO₂ transparent layer can be achieved by APCVD. The source SnCl₂ vapor, heated to its boiling point, is distributed to the inside of a tubular substrate with a temperature approximately 500˜600° C. at atmospheric pressure. The oxygen in the air will react with SnCl₄ to form a solid SnO₄ on the inside of substrate 1501. It is important to have the precursors evenly distributed along the tubular substrate 1501 to get a uniform layer. Precursors 1524 are distributed evenly along the tubular axis by a multi-zone distribution system 1525. f1, f2 and f3 indicate precursor flow. The flow rate of precursors in each zone is independently controlled and the substrate may rotate continuously or any suitable interval during the process to get uniform film deposition. In addition one or more layers may be deposited by Low Pressure Chemical Vapor Deposition (LPCVD). A textured ZnO transparent conductive layer may be deposited on the inside of substrate 1501. The tubular substrate 1501 temperature in this application may be maintained approximately 150° C.

The present invention contemplates methods comprising plasma enhanced chemical vapor deposition to deposit films having excellent film uniformity. In one embodiment the process plasma is confined inside the tube and the tube is rotated, preferably continuously during process. In another embodiment confining feedstock gas during the deposition process can effectively reduce both material and maintenance cost, and lowers the requirement on the effluent treatment systems.

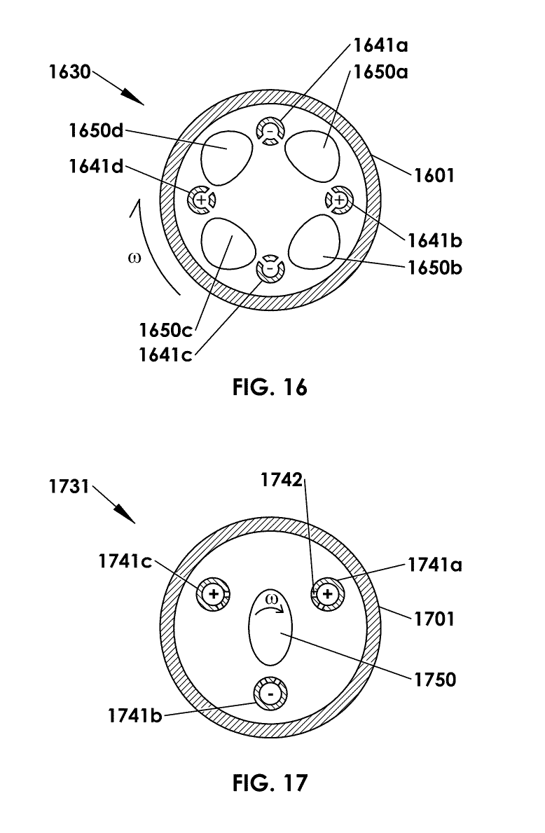

FIG. 16 illustrates a process of making a tubular photovoltaic cell 1630 in which an even-numbered of multi-electrodes 1641a, 1641b, 1641c and 1641d are circularly arranged inside a tubular substrate 1601 for layer deposition thereon. By applying 180 degree out of phase RF power to an even-numbered of multi-electrodes 1641a, 1641b, 1641c and 1641d, process plasma is generated to facilitate the film deposition on the inside of the tubular substrate. The tubular substrate may rotate continuously during the process to get uniform film deposition. Electrodes 1641a, 1641b, 1641c and 1641d comprise multiple openings such as that illustrated in electrode 1641a. The process gas mixture may be delivered to the inside of the tubular substrate 1601 through electrode rods 1641a, 1641b, 1641c and 1641d with openings, and RF power is applied to each of the electrode rods 1641a, 1641b, 1641c and 1641d and adapted to drive adjacent electrode 180 degree out of phase from one another. Only 4 electrode rods are shown however the invention contemplates that any even number of electrode rods can be used. The rods may be hollow or partially hollow, so long as they are capable of delivering an adequate amount of process gas. With a circular symmetrical arrangement of an even numbered electrode rods and the alternating polarity of electrode rods, the majority of plasma 1650a, 1650b, 1650c and 1650c should generate between adjacent electrode rods. During the processing period, the tubular substrate will rotate to get an even deposition of thin film layers.

FIG. 17 illustrates an embodiment of the present invention in which an odd number of hollow electrode rods 1741a, 1741b and 1741c with openings 1742 along its axis positioned within tubular substrate 1701. Only three electrode rods are shown. Other odd number of electrodes may be used to generate a rotating plasma within a tubular substrate. A process gas mixture may be delivered to the inside of tubular substrate 1701 through electrode rods 1741a, 1741b and 1741c with openings 1742. RF power is applied to each of the electrode rods 1741a, 1741b and 1741c and adapted to drive adjacent electrodes 120 degree out of phase from one another. With the circular symmetrical arrangements of the electrode rods 1741a, 1741b and 1741c and the 120 degree phase difference between the two electrodes, a rotating high density plasma 1750 is created at the center of the tubular substrate 1701. The diffusion of high intensity plasma from the center provides excellent film deposition onto the inner wall of tubular substrate 1701.

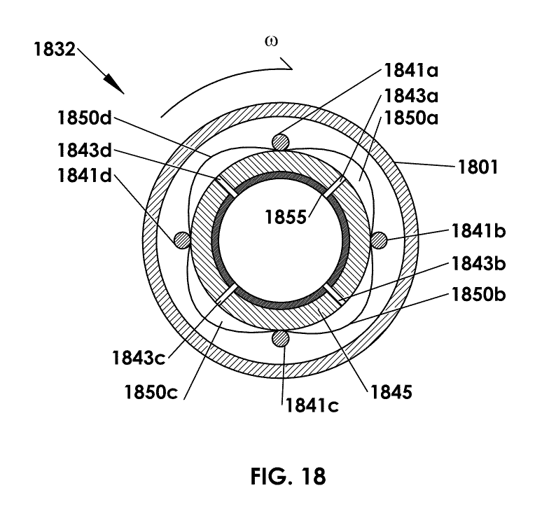

FIG. 18 illustrates a process of depositing layers 1832 comprising an even number of electrodes 1841a, 1841b, 1841c and 1841d arranged preferably symmetrically around a hollow insulator 1845 comprising openings 1843a, 1843b, 1843c and 1843d. Optional metal shield 1855 will prevent plasma from entering the hollow insulator 1845. The invention contemplates that a process gas may be delivered to the inside of the tubular substrate 1801 through the openings 1843a, 1843b, 1843c and 1843d on the hollow insulator 1845, and a RF power supply connected to each of the electrode 1841a, 1841b, 1841c and 1841d and adapted to drive an adjacent electrode or 1841a, 1841b, 1841c and 1841d 180 degree out of phase from one another. The optional metal shield 1855 will prevent plasma generation inside the hollow insulator 1845. Only four electrodes are shown. In applications, any even number of electrodes with any shape can be used. With the circular symmetrical arrangements of any number electrodes and the alternating polarity, plasma 1850a, 1850b, 1850c and 1850d will be created between adjacent electrodes outside hollow insulator 1845.

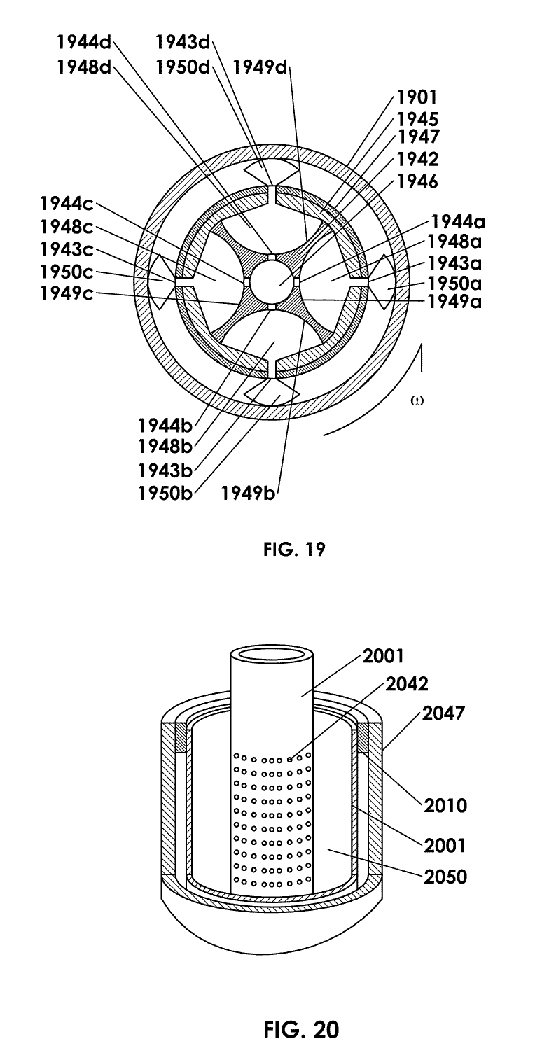

FIG. 19 illustrates a process according to the invention using a multi-chamber hollow cathode 1942 for the deposition of thin films and or layers of thin films inside a substrate 1901. The hollow cathode 1942 is surrounded by insulating layer 1945 and anode enclosure 1947. Process gases are fed through the center 1946 of the hollow cathode 1942 and through cathode openings 1944a, 1944b, 1944c and 1944d. The process gas is designed to communicate and flow through the gas discharge chambers 1948a, 1948b, 1948c and 1948d through gas discharge chamber openings 1943a, 1943b, 1943c and 1943d, respectively as a jet stream of process plasma 1950a, 1950b, 1950c and 1950d respectively with supersonic velocity, driven by the pressure gradient and electrical potential gradient set between the cathode 1942 and anode enclosure 1947. Preferably the anode enclosure 1947 exposes the cathode to gases only through cathode openings 1943a, 1943b, 1943c and 1943d. The high ratio between the cathode area 1949a, 1949b, 1949c and 1949d and the exposed anode area through openings 1943a, 1943b, 1943c and 1943d respectively facilitates a strong potential gradient around openings 1943a, 1943b, 1943c and 1943d which combined with the pressure gradient creates supersonic process plasma jet stream required for plasma enhanced chemical vapor deposition. Hollow cathode 1942 has four gas discharge chambers 1948a, 1948b, 1948c and 1948d which are formed between the insulator layer 1945 and the concave cathode 1949a, 1949b, 1949c and 1949d. The invention contemplates that any number of gas discharge chambers having a concave surface are suitable for deposition according to the instant invention. Preferably the invention uses four.

FIG. 20 illustrates a process and apparatus for depositing a thin film on the inside of a tubular substrate 2001 comprising a hollow electrode tube 2042 with openings coupled with an anode enclosure 2047. The optional anode enclosure 2047 makes tight contact with pre-installed rings 2010 on the tubular substrate 2001 so that the effusions of process gas mixture from the inside of tubular substrate will not leak into the gap between the substrate 2001 and the anode enclosure 2047. By applying negative biased RF power to the hollow electrode tube 2042, the capacitive coupled process plasma 2050 will be created evenly in the circumferential sense around the inside of the tubular substrate 2001 resulting in excellent deposition. In another embodiment, not illustrated, the substrate 2001 may rotate alone or in combination with the hollow electrode tube 2042. They may rotate the same directions or opposite directions.

Physical vapor deposition (PVD or sputtering) is commonly used to deposit the transparent conductive layer of a photovoltaic device. Materials like aluminum doped zinc oxide, metal layers, SiN are commonly formed by the physical vapor deposition. In order to speed up the process, magnetron sputtering is employed in the prior art. Magnetron sputtering uses a magnetic field to trap electrons in a region near the negatively biased target, which is made of the desired material to be disposed onto the substrate. The trapped electrons help sustain the process plasma and cause the target to increase release of the desired materials.

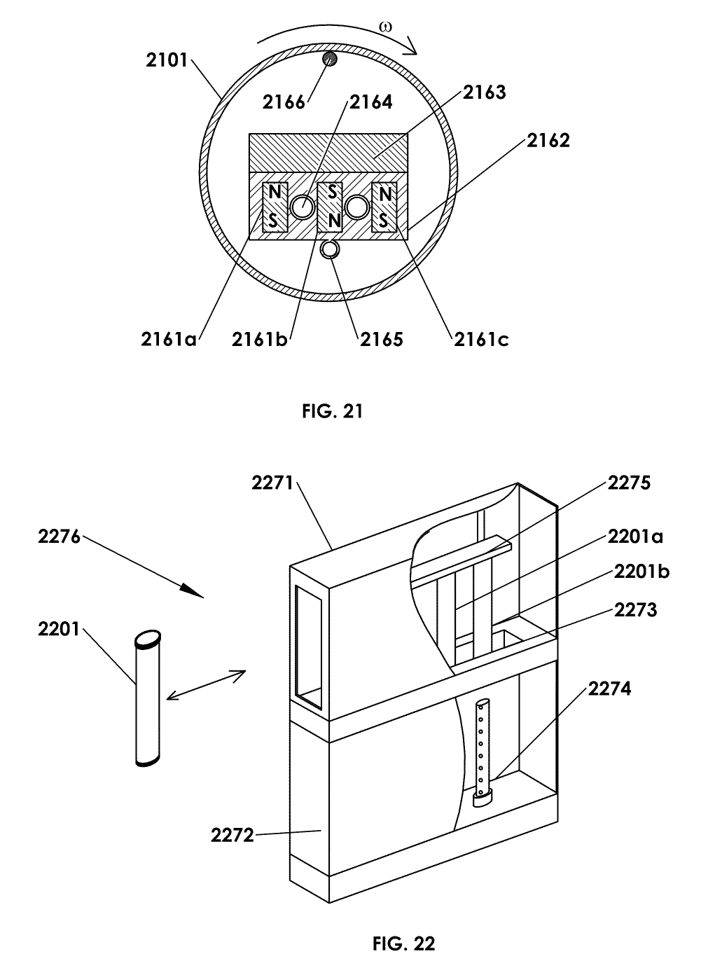

FIG. 21 illustrates a novel use of magnetron sputtering to deposit thin films inside a tubular substrate 2101. Permanent magnets 2161a, 2161b and 2161c are arranged inside magnetron casing 2162 so that a magnetic flux intensity of about 500 G is created on the surface of target 2163, which is attached onto the magnetron casing 2162. The target mounting mechanism is not shown in FIG. 21. The target 2163 can be made of any material suitable for magnetron sputtering process such as aluminum doped zinc oxide, zinc oxide, aluminum, silver and/or gold. The magnetron cooling pipe 2164 is buried inside the magnetron casing 2162 and communicates externally so that cooling media like water can circulate inside the magnetron casing 2162. The process gas such as argon may be delivered to the inside of the tubular substrate 2101 through opening 2165 which may comprise a tube which has proper arranged apertures throughout. The magnetron casing of 2162 is negatively biased with or without the RF power. An anode wire or rod 2166 can be inserted into the tubular substrate 2101 on the side of target. The substrate 2101 may rotate during the process to accomplish uniform thin film deposition.

FIG. 22 illustrates a stand-alone platform 2276 and process of present invention which can be used to deposit thin films on the inside of tubular substrates 2201a and 2201b through LPCVD, PECVD or PVD processes. Inventor's apparatus contains two vertically stacked-up chambers, the load lock chamber 2271 and the process 2272. Between these two chambers is the slit valve 2273, which keeps the process chamber 2272 in constant vacuum appropriate to the deposition process. The optional process heater and the substrate rotating mechanism are not shown. The process units 2274 are coaxial with the tubular substrates 2201a and 2201b (only one show), which move into/out of the process chamber 2272 vertically through the slit valve 2273 by the tubular substrate handling loading mechanism 2275. Multiple tubular substrates 2201a are loaded/unloaded through the atmospheric gate valve (not shown) on the side of the load lock chamber 2271 either by an industry robot or by a tub rack which must be removed from the load lock chamber after the tube loading. A typical operating sequence comprises:
1) keep slit valve 2273 closed
2) ventilate the load lock chamber 2271
3) open the gate valve of load lock chamber
4) Unload the processed tubes from the tube handling system 2275 inside the load lock chamber 2271.
5) load the unprocessed tubes onto the tube handing system 2275 in the load lock chamber
6) closed the gate valve,
7) pump down the load lock chamber pressure to desired level
8) open the slit valve 2273,
9) lower the tubular substrates down to the process chamber 2272, the tubular substrates and the process units 2274 are co axial
10) the holding and rotating mechanism, not shown in the drawing, holds the tubular substrates vertically in position, coaxially with the process units
11) the tubular substrate handling system 2275 moves back to load lock chamber
12) Close the slit valve 2273
13) When the deposition process is finished, open the slit valve 2273
14) Lower the tubular substrate 2275 down to the process chamber and grab the processed tubes
15) The process holding/rotating mechanism releases the tubes
16) The tubular substrate handling system 2275 moves back to load lock chamber 271
17) Close the slit valve 2273

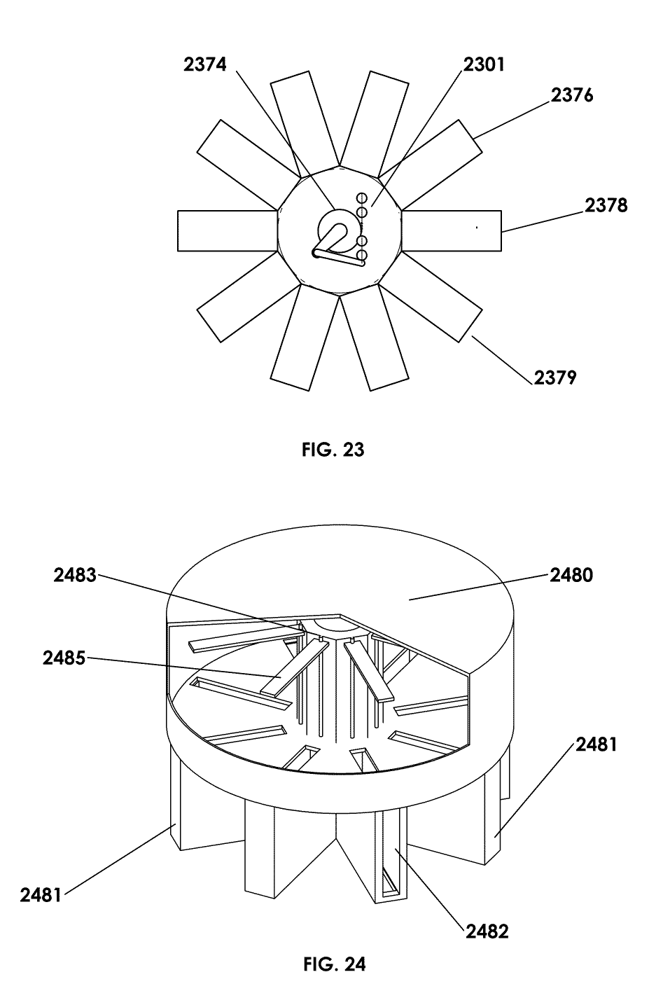

FIG. 23 illustrates multiple standalone platforms 2376 arranged around an industrial robot 2374. Tube loading area 2378 and pre-heating chamber 2379 provide for efficient operation. The exact number of the standalone platforms, loading areas 2378 and pre-heating chambers 2379 around the robot may be optimized for efficient production.

FIG. 24 illustrates an apparatus comprising a buffer chamber 2480 to reduce the vacuum pumping down time. In applications where the process chamber base pressure are very low, about 10⁻⁶ Torr, it may be necessary to separate the process chamber from the load lock chamber by means of buffer chamber to reduce the process pumping down time. In the illustration common buffer chamber 2480 is on top of process chambers 2481 and load lock chamber 2482. There is slit valve, not shown between each individual chamber and the common buffer chamber 2480. The ambient gate valve for load lock chamber is not shown. Inside the common buffer chamber 2480, there comprises a rotatable carousel 2483 comprising one or multiple tubular substrate handling systems 2485, each of which has an independent driving system to move the tubular substrates vertically during load/unload period. The tubular substrates communicate with the ambient environment through the load lock chamber 2482. Both the process chamber 2481 and common buffer chamber 2480 are kept at desired vacuum level.

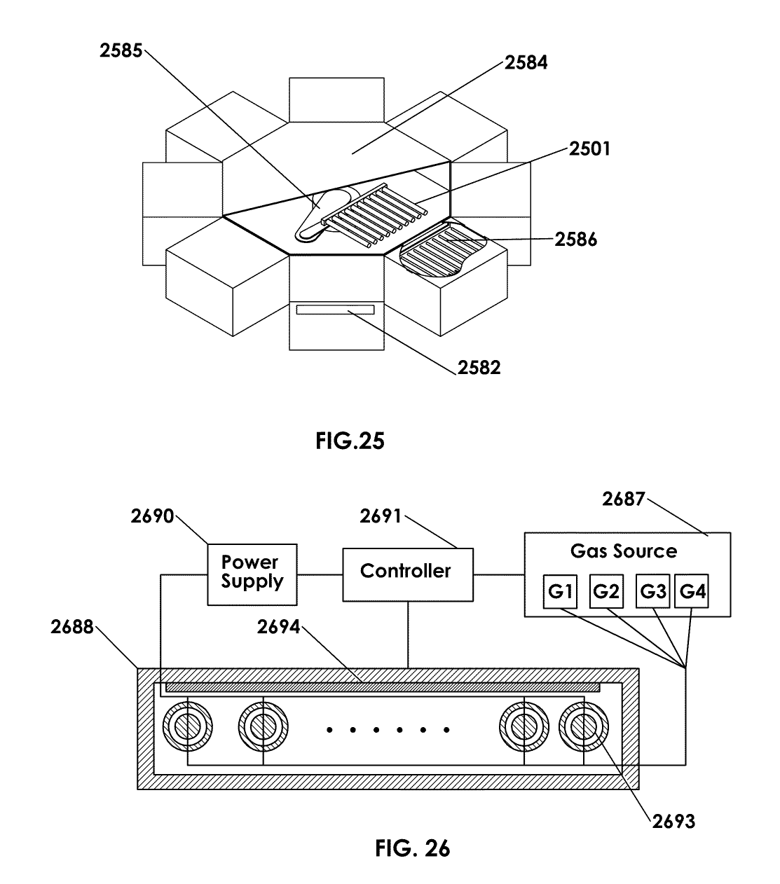

FIG. 25 illustrates a vacuum robot hub 2584 is utilized to reduce the process chamber vacuum pumping down time. In this embodiment the vacuum robot 2574 inside the vacuum hub 2584 transfers tubular substrate 2501 among the chambers around it. The load lock chamber 2582 will also serve as a preheat chamber if necessary. The process units 2586 may be arranged horizontally, so are the tubular substrates 2501 in this configuration.

FIG. 26 illustrates a substrate processing system 2684 that can be used to deposit thin films on the inside of tubular substrates 2601. This apparatus 2684 comprises a process chamber 2688, a gas distribution pane 2689, a power supply system 2690 and a controller 2691. Actions/reactions of the deposition process are contained primarily inside tubular substrates 2601 especially during PECVD and PVD process. During the LPCVD process however, extra shield could be employed to isolate the precursor from depositing on the outside of the tubular substrates 2601. The process units 2693 differ depending on individual process. Power supply 2690 also differs for each individual process, in one embodiment of present invention, power supply 2690 contains negatively biased RF power for the PECVD process, in another embodiment of present invention, power supply 2690 contains negatively biased DC power or DC pulsed power or low frequency AC for the PVD process. The process heater 2694 is not required for PVD process, while in LPCVD or PECVD process these heaters are used for maintaining the tubular substrates' temperature.

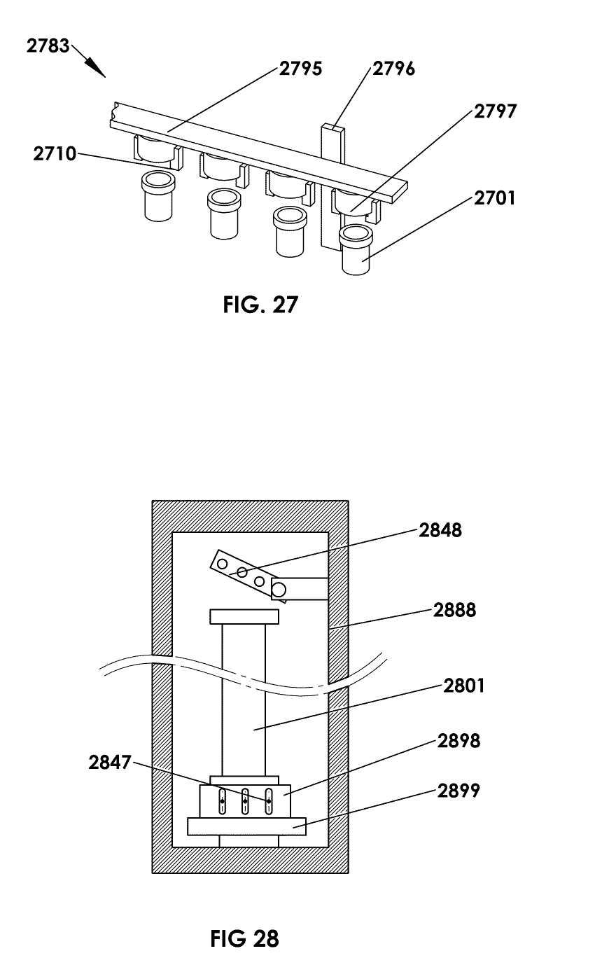

FIG. 27 illustrates an industrial robot according to the instant invention moving tubular substrates 2701 from a tubular substrate rack and subsequently transports the tubular substrates 2701 between the load lock chamber and the process chamber in standalone configuration. It contains a tubular substrate handling platform 2795, which moves vertically to transport arrays of tubular substrates 2701 between the process chamber and the load lock chamber. The tubular substrates 2701 have the pre-installed rings 2710 on each end of the tube. The substrate grippers 2797 close or open to hold or release the glass.

FIG. 28 illustrates an apparatus of present invention which holds and rotates the tubular substrates 2801 during the process period. Tubular substrate base support 2847 which is mounted on the driving gear/wheel 2899. The gas and electric power pass through the hollow center of the driving gear 2899 and base support 2898. The excessive gas precursors pass through the holes 2847 on the base support 2898 and top support 2848. The top support opens or closes to allow the substrates into/out off the process chamber 2888. The normal tube handling sequence is as following
1. Tubular substrate top support 2848 in open position
2. The tubular substrate handling system lower substrates down to the process chamber. The bottom of the substrates rests on the base support 2898.
3. The top supports 2848 close and press the tubular substrates 2801 onto the base supports 2898
4. The grippers on the tubular substrate handling system open and the substrate handling system moves out of the process chamber
5. During process, the driving gear 2899 rotates and so the tubular substrates 2801 get uniform film deposition

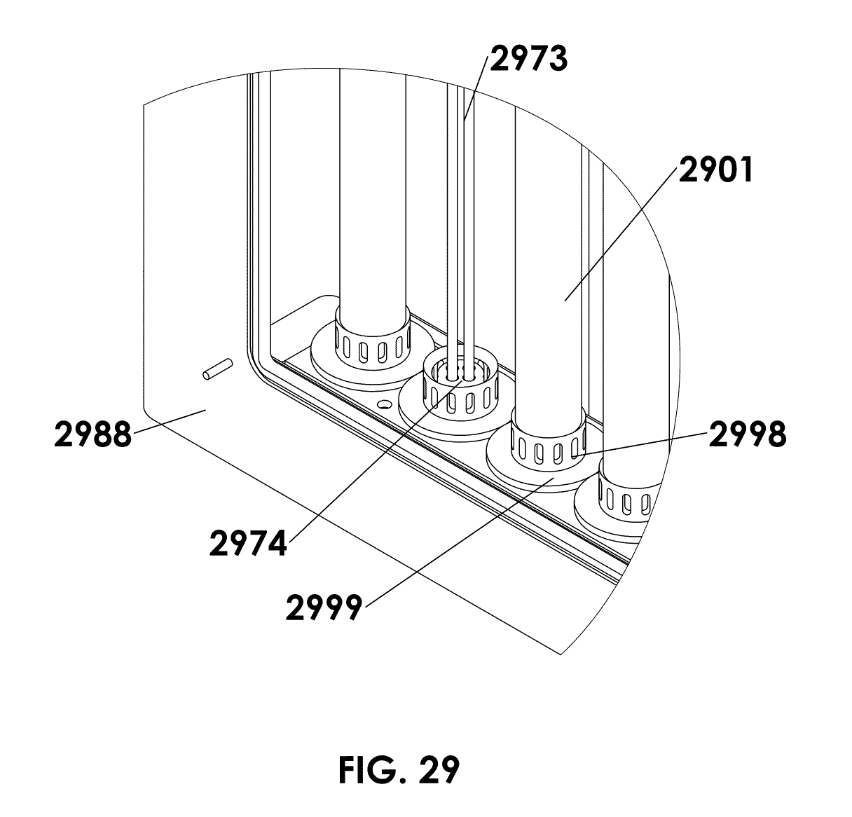

FIG. 29 illustrates an apparatus of the present invention for a PECVD process comprising multiple RF tubes 2973 which are used to deliver a gas mixture through holes along the RF tube. Due to the high RF frequency, a thin wall stainless tube is used for the RF power delivery. Ceramic isolator 2974 is used as housing for RF tube adapter (not shown) where both RF power and the process gas are delivered to the RF tube. The base support 2998 will support one end of the tubular substrate. The driving gear 2999 keeps the substrates 2901 rotating during the normal process.

What is claimed is:

1. A photovoltaic device, comprising:
a tubular substrate,
a transparent conductive layer disposed inside said substrate,
a semiconductor junction layer disposed on said transparent conductive layer,
and a back electrode disposed on said semiconductor junction layer.

2. A photovoltaic device according to claim 1, further comprising:
at least one sealing ring disposed at an end of the photovoltaic device.

3. A photovoltaic device according to claim 2, further comprising:
a sealing cap attached to the sealing ring, and
the device is hermetically sealed.

4. A photovoltaic device according to claim 1, wherein:
the device comprises a plurality of photovoltaic cells separated by a series of grooves.

5. A photovoltaic device according to claim 4, wherein:
each of said plurality of photovoltaic cells is the same or different and has a groove extending less than 60 degrees from a center axis of the device.

6. A photovoltaic device according to claim 4, wherein:
said groove extends non-orthogonally around the tube.

7. A photovoltaic device according to claim 1, wherein:
the back electrode is transparent.

8. A photovoltaic device according to claim 1, further comprising:
a second device disposed inside the photovoltaic device, said second device is selected from the group consisting of a photovoltaic device and a battery.

9. A photovoltaic device according to claim 1, further comprising a reflective surface on a portion of a surface of the tubular device.

10. A method of forming a thin film, comprising:
generating a plasma inside a tube using one or more electrodes, wherein:
said plasma is configured to coat the inside of the tube uniformly.

11. The method of claim 10, wherein:
the plasma is generated using an even number of electrodes distributed at an equidistance symmetrically arranged around a center axis of the tube.

12. The method of claim 10, wherein:
the plasma is generated between adjacent electrodes.

13. The method of claim 10, wherein:
the tube rotates during deposition.

14. The method of claim 10, wherein:
the plasma is generated using odd number of electrodes distributed at an equidistance symmetrically arranged around a center axis of the tube.

15. The method of claim 11, wherein:
the plasma is generated in the center of the tube.

16. The method of claim 12, wherein:
the plasma is rotating circumferentially inside the tube.

17. The method of claim 10, wherein:
the process gas is delivered by a hollow electrode or a hollow insulator.

18. A method according to claim 17, wherein:
the hollow electrode comprises a shield to keep the plasma out of the hollow insulator.

19. An electrode, comprising:
a hollow tubular central portion,
at least two gas discharge chambers in communication with said hollow tubular central portion through a gas inlet opening,
said gas discharge chamber has a gas discharge chamber opening designed to communicate with an anode, and
said gas discharge chamber has a concave surface whereby:
when a gas is fed through said gas inlet opening and through said gas discharge chamber opening, a plasma is created.

20. An electrode according to claim 19, wherein:
the electrode comprises four chambers.
